(19) United States
(12) Patent Application Publication
(10) Pub. No.: US 2025/0258428 A1
(43) Pub. Date: Aug. 14, 2025

(54) RETICLE CONSTRAINT FOR A RETICLE CONTAINER

(71) Applicant: ENTEGRIS, INC., Billerica, MA (US)

(72) Inventor: Anthony M. Tieben, Belle Plaine, MN (US)

(21) Appl. No.: 19/046,399

(22) Filed: Feb. 5, 2025

Related U.S. Application Data
(60) Provisional application No. 63/691,312, filed on Sep. 5, 2024.
(60) Provisional application No. 63/553,049, filed on Feb. 13, 2024.

(51) Int. Cl. G03F 1/66; G03F 7/00

(52) U.S. Cl. CPC G03F 1/66; G03F 7/70741; G03F 7/70766

(57) ABSTRACT

Reticle containers can include reinforcement supports that include support features configured to contact and thereby support corner contacts when shocks deflect corner contacts of the reticle container. The reinforcement supports can be integral to a portion of the reticle container such as a cover portion thereof, or provided on an insert configured to attach to a feature of the reticle container. The reinforcement supports can attach over the corner contacts. The reinforcement supports can additionally include contact regions configured to receive contact from the reticle in the event of a shock.

### CROSS-REFERENCE TO RELATED APPLICATIONS

This application claims the benefit under 35 USC 119 of U.S. Provisional Patent Application No. 63/553,049, filed Feb. 13, 2024, and U.S. Provisional Patent Application No. 63/691,312, filed Sep. 5, 2024, the disclosures of which are hereby incorporated herein by reference in their entirety.

### FIELD

This disclosure is directed to containers for reticles, particularly containers including constraints for reducing reticle movement when the container is subjected to a shock event such as being dropped.

### BACKGROUND

Reticles can be contained within storage containers for storage, shipping and the like. During shipping, shocks can occur, for example when the container is dropped, bumped, or otherwise experiences impact. The shocks can dislodge the reticle from the support structures provided in the container, causing damage to the reticle, either directly, or as a result of the reticle contacting other features within the container. This damage can include damage to the functional portions of the reticle, rendering the reticle unsuitable for use.

### SUMMARY

This disclosure is directed to containers for reticles, particularly containers including constraints for reducing reticle movement when the container is subjected to a shock event such as being dropped.

By using additional reinforcements, the range of deflection for existing corner contacts can be constrained, thereby preventing the corner contacts from deflecting to an extent where the reticle can be dislodged within the reticle container. The reinforcements can also include contact surfaces that can contact the reticle to constrain movement of the reticle during shock events to prevent the reticle from being dislodged.

In an embodiment, a reticle container includes a first container segment, a second container segment, and one or more corner contacts. Each corner contact includes one or more arms, each arm ending in a contact surface configured to contact a reticle within a reticle accommodation space defined by the first container segment and the second container segment. The reticle container further includes one or more reinforcement supports. Each of the one or more reinforcement supports includes at least one support feature configured to contact at least one of the one or more arms when said at least one of the one or more arms is deflected to a threshold deflection.

In an embodiment, at least some of the one or more reinforcement supports extend from the first container segment. In an embodiment, the support feature includes an elongated post. In an embodiment, the reticle container further includes one or more inserts, wherein at least some of the one or more reinforcement supports are provided on the one or more inserts. In an embodiment, at least some of the one or more inserts are configured to attach to one of the one or more corner contacts. In an embodiment, at least some of the one or more inserts are configured to attach to the first container segment. In an embodiment, at least some of the reinforcement supports include a contact configured to face the reticle within the reticle accommodation space. In an embodiment, the contact includes a flat surface.

In an embodiment, an article includes a shipping constraint for a reticle container. The shipping constraint includes an attachment interface configured to allow attachment of the shipping constraint to the reticle container and at least one reinforcement support. The reinforcement support includes at least support feature configured to be contacted by an arm of a corner constraint of the reticle container, when said arm is deflected to a threshold deflection.

In an embodiment, the attachment interface is an aperture configured to fit over a portion of the corner constraint. In an embodiment, the support feature includes an elongated post. In an embodiment, the reinforcement support includes a contact configured to face a reticle within a reticle accommodation space of the reticle container. In an embodiment, the contact includes a flat surface. In an embodiment, the article is formed of polycarbonate. In an embodiment, the article is formed of polyether-ether-ketone (PEEK).

In an embodiment, a method of handling a reticle includes providing a reticle container. The reticle container includes a first container segment, a second container segment, a plurality of corner contacts configured to contact the reticle, and a plurality of reinforcement supports. The method further includes placing a reticle into a reticle accommodation space defined by the first container segment and the second container segment, such that the corner contacts are in contact with the reticle. The method also includes transporting the reticle container when the reticle is in the reticle accommodation space of the reticle container. When the reticle container is subjected to a shock, at least some of the corner contacts deflect such that said corner contacts come into contact with at least one of the reinforcement supports, thereby stopping further deflection of said corner contacts.

In an embodiment, the reinforcement supports are provided on an insert configured to be attached to the reticle container, and the method further includes installing the insert into the reticle container. In an embodiment, when the reticle container is subjected to the shock, the reticle comes into contact with at least one flat surface provided on at least one of the reinforcement supports. In an embodiment, the shock is a dropping of the reticle container from a height of 12 inches or less, and the reticle remains in contact with the corner contacts following the shock.

### BRIEF DESCRIPTION OF THE DRAWINGS

FIG. 1 shows an exploded view of a reticle container according to an embodiment.

FIG. 2 shows a portion of a reticle container according to an embodiment.

FIG. 3A shows a reinforcement support according to an embodiment.

FIG. 3B shows another view of the reinforcement support of FIG. 3A.

FIG. 4 shows a method according to an embodiment.

### DETAILED DESCRIPTION

This disclosure is directed to containers for reticles, particularly containers including constraints for reducing reticle movement when the container is subjected to a shock event such as being dropped.

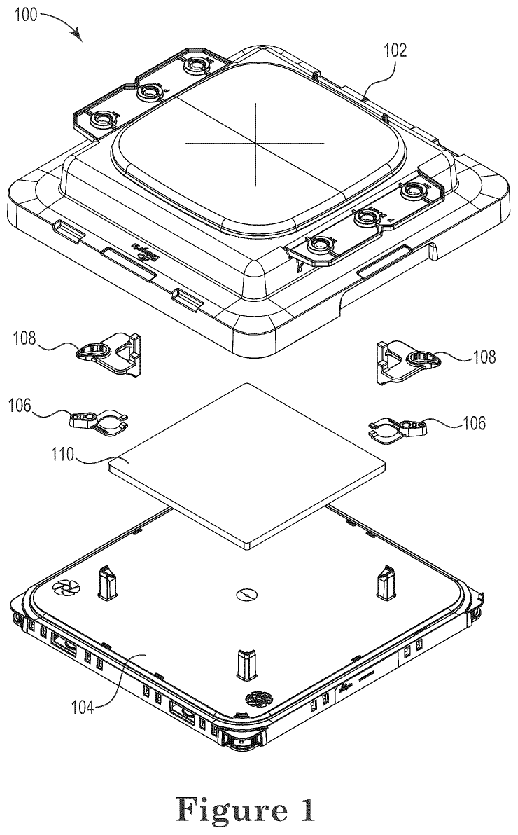

FIG. 1 shows an exploded view of a reticle container according to an embodiment. Reticle container 100 includes first segment 102 and second segment 104. The reticle container 100 further includes corner contacts 106 and reinforcement supports 108. Reticle 110 can be stored within the reticle container.

Reticle container 100 is a storage and/or transport container for a reticle. The reticle container 100 can be, for example, a reticle shipping container. The reticle container 100 can be formed of one or more polymer materials. The reticle container is configured to be capable of accommodating a corresponding reticle 110, such as a standard photolithography reticle, a large-format photolithography reticle, or the like.

First segment 102 is configured to form an upper portion of the reticle container 100. First segment 104 can be, for example, a cover, a pod dome, or the like. First segment is configured to be attached to second segment 104 such that first segment 102 and second segment 104 define an internal space capable of accommodating the reticle 110.

Second segment 104 is configured to form a lower portion of the reticle container 100. Second segment 104 can be, for example, a pod door or the like. In an embodiment, the reticle container 100 can be opened by separating the first segment 102 and the second segment 104 and lowering the second segment away from the first segment 102.

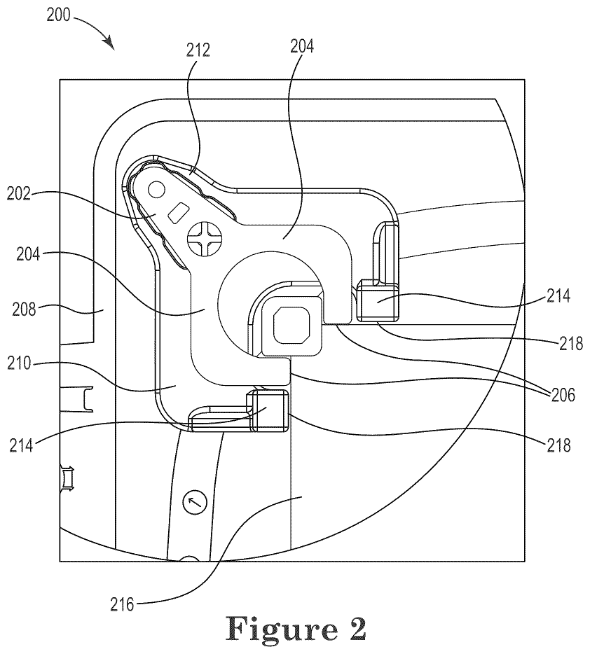

Corner contacts 106 can be provided in one of first segment 102 and second segment 104. The corner contacts can be configured to contact the reticle 110 such that the reticle 110 is retained in a predetermined position within reticle container 100 when the first segment 102 and the second segment 104 are joined together. The corner contacts 106 can each be configured to contact the reticle 110 at non-functional portions thereof, such as at an edge of the 110, on non-functional surfaces of the reticle such as surfaces near the outer perimeter, or the like. The non-functional surfaces can be defined as any portion of the reticle outside of functional components, such as, for example, the photolithography mask portion of the reticle. In embodiments, the non-functional surfaces can be defined according to suitable standards for reticle design, or the like. The corner contacts 106 can be provided on one or both of first segment 102 and second segment 104. In an embodiment, one or more of the corner contacts 106 or portions thereof are formed integrally with the first segment 102 or second segment 104. In an embodiment, one or more of the corner contacts 106 or portions thereof are provided on one or more inserts configured to be attached to first segment 102 or first segment 104. In an embodiment, the corner contacts 106 each include a point of fixture to first segment 102 or second segment 104, one or more arms each extending from the point of fixture, and a contact surface provided at an end of each of the one or more arms. The arms can be configured to be flexible, such that the arms can deform when the reticle is moved, for example during a shock event experienced by the reticle container 100. A non-limiting example of a corner contact 106 is provided in the corner contact 202 shown in FIG. 2 and discussed below.

Reinforcement supports 108 are features configured to support the corner contacts 106 such that the reinforcement supports 108 obstruct movement of portions of the corner contacts 106, so as to prevent deformation of the corner contacts 106 beyond a certain point. The reinforcement supports 108 can be configured such that deformation of the corner contacts 106 is restricted at or prior to a point where the corner contacts 106 would lose contact with and/or control of the position of reticle 110. Reinforcement supports 108 can be configured such that corner contacts 106 continue to retain the reticle even under significant shock events. Reinforcement supports 108 can include, for example, one or more vertical posts placed in paths over which the corner contacts 106 are configured to deform. In such an embodiment, the vertical posts can have any suitable cross-sectional shape, for example a square, rectangular, circular, elliptical, or the like. In an embodiment, the vertical posts provide a surface that can be spaced apart from the reticle 110 when the reticle 110 is in the reticle container 100, but capable of receiving impact of the reticle 110 when reticle 110 moves during a shock event. In embodiments, the vertical posts can be straight or tapered. In an embodiment, at least some of the reinforcement supports 108 are provided as or included in one or more inserts configured to be attached to one or both of first segment 102 and second segment 104. In an embodiment, at least some of the reinforcement supports 108 extend from the first segment 102.

Reticle 110 is a reticle to be stored in the reticle container 100. Reticle 110 can be any suitable reticle, such as, for example, a reticle including a photolithography mask. The reticle 110 can be a standard size reticle, a large format reticle, or the like. The reticle 110 can have any suitable profile, for example a square or rectangular profile. The reticle container 100 can be sized and shaped to contain a particular corresponding shape of the reticle 110. Reticle 110 can include a functional region, such as the mask used during photolithography processes or the like, and a non-functional region outside of the functional region. The non-functional regions can be one or more regions that can receive contact from corner contacts 106 and/or the reinforcement supports 108 without adverse effects on the function of the reticle 110. The non-functional regions can include, but are not limited to, perimeter portions of the upper and lower facing surfaces of the reticle 110, an outer wall defining the perimeter of the reticle 110, and the like.

FIG. 2 shows a portion of a reticle container according to an embodiment. Reticle container 200 includes corner contact 202. Corner contact 202 includes arms 204 ending in reticle contact surfaces 206. The corner contact 202 is installed into a container segment 208. Reinforcement support 210 is included in reticle container 200. The reinforcement support includes attachment feature 212 and support features 214. Reticle 216 is retained by the corner contact 202.

Reticle container 200 is a container for storage and/or transportation of a reticle. The reticle container can be, for example, the reticle container 100 as described above and shown in FIG. 1. The reticle container 200 can be, for example, a shipping container for the reticle.

Corner contact 202 is a component of reticle container 200 configured to contact the reticle 216 so as to secure the reticle 216 in position within the reticle container 200. The corner contact 202 is attached to container segment 208. The corner contact 202 includes arms 204. Arms 204 extend from the corner contact 202. Arms 204 are configured to be deflected during contact with the reticle 216, for example to accommodate small shocks while remaining in contact with reticle 216. The arms 204 can be formed of any suitable material allowing suitable deflection of arms 204. Arms 204 can be shaped to provide the suitable deflection thereof, for example having a thickness and/or cross-sectional shape selected to allow for such deflection. The deflection of arms 204 can be at any point along the arms 204 as they extend from corner contact 202. Suitable deflection of the arms 204 can include sufficient deflection such that reticle contact surfaces 206 each respectively make suitable contact with a non-functional region of the reticle 216. In an embodiment, the arms 204 can deflect such that reticle contact surfaces 206 make edge contact with sides of the reticle 216. In an embodiment, arms 204 can be configured such that deflection to make suitable contact with the reticle is movement of the reticle contact surfaces 206 by approximately 0.1 inches to 0.01 inches. Arms 204 include reticle contact surfaces 206. Reticle contact surfaces 206 can be along or at ends of respective arms 204. In an embodiment, each arm 204 includes one or more of the reticle contact surfaces 206. Reticle contact surfaces 206 are configured to contact the reticle 216 such that reticle 216 is secured within the reticle container 200. The reticle contact surfaces 206 and/or arms 204 can be configured such that the reticle contact surfaces make contact with reticle 216 only at non-functional regions of the reticle 216, as discussed further below with respect to reticle 216.

Container segment 208 is a portion of reticle container 200 configured to at least partially define a space for accommodating reticle 216. The container segment 208 shown in FIG. 2 can be a lower portion of the reticle container 200, with a non-limiting example of such a lower portion of a reticle container being the second container segment 104 described above and shown in FIG. 1. In an embodiment, container segment 208 can include or allow attachment of the corner contact 202.

Reinforcement support 210 is configured to be included in reticle container 200 such that the reinforcement support 210 can constrain the movement of arms 204 during significant shock events, such as dropping or striking of the reticle container 200. Reinforcement support 210 can be an insert, for example including an attachment interface 212, or can be formed integrally with the reticle container 200, for example by having support features 214 extend from a container segment. Reinforcement support 210 can further be configured to receive contact from reticle 216 during severe shock events, for example on flat faces 218 provided on the reinforcement support 210.

Attachment interface 212 allows the reinforcement support 210 to be attached to reticle container 200. In the embodiment shown in FIG. 2, the attachment interface 212 is configured to fit over a portion of the corner contact 202 to form a press-fit therewith, such that reinforcement support 210 is securely retained within reticle container 200. The attachment interface 212 can include one or more engagement features, such as press-fit surfaces, slots, tabs, snap-fit features, or any other suitable features for forming a mechanical connection between reinforcement support 210 and the reticle container 200. In embodiments, the attachment interface 212 can be configured to attach the reinforcement support 210 to the container segment 208 or to another container segment such as first segment 102 as discussed above and shown in FIG. 1.

Support features 214 are features configured to restrict the movement of features of the corresponding corner contact. In an embodiment, support features 214 can extend into a deflection path of a corresponding arm 204 of a corner contact 202, so as to obstruct further deflection by said corresponding arm 204. Support features 214 can be, for example, vertically extending posts having a square or rectangular cross-section including a flat face 218 facing outwards towards the reticle 216. The flat faces 218 can be configured such that when the reticle is in its ordinary position within the reticle container, the flat faces 218 will be spaced apart from the reticle 216. In an embodiment, the reticle can come into contact with the flat faces 218 to restrict movement of the reticle and prevent the reticle from being ejected. In other embodiments, the vertically extending posts can have an elliptical or circular cross-section providing a contact surface as opposed to the flat face 218.

Reticle 216 is a reticle to be stored in the reticle container 200. Reticle 216 can be any suitable reticle, such as, for example, a reticle including a photolithography mask. The reticle 216 can be a standard size reticle, a large format reticle, or the like. The reticle 216 can have any suitable profile, for example a square or rectangular profile. Reticle 216 can be, for example, reticle 216 as described above and shown in FIG. 1. Reticle 216 can include a functional region, such as the mask used during photolithography processes or the like, and a non-functional region outside of the functional region. The non-functional regions can be one or more regions that can receive contact from reticle contact surfaces 206 and/or the reinforcement supports 210 without adverse effects on the function of the reticle 216. The non-functional regions can include, but are not limited to, perimeter portions of the upper and lower facing surfaces of the reticle 216, an outer wall defining the perimeter of the reticle 216, and the like.

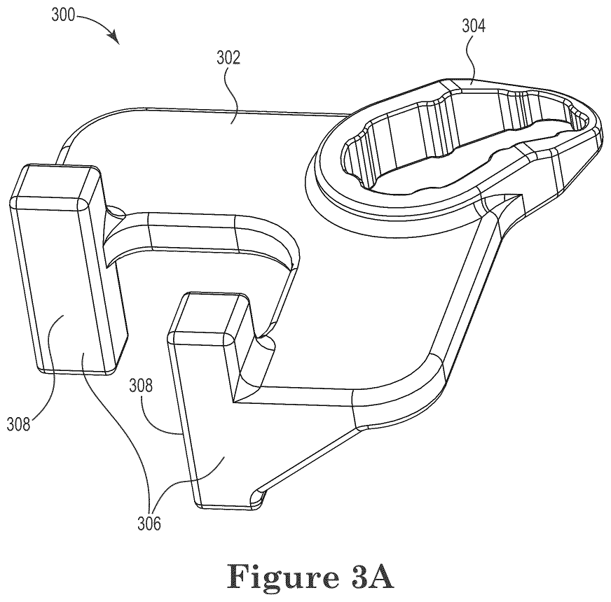

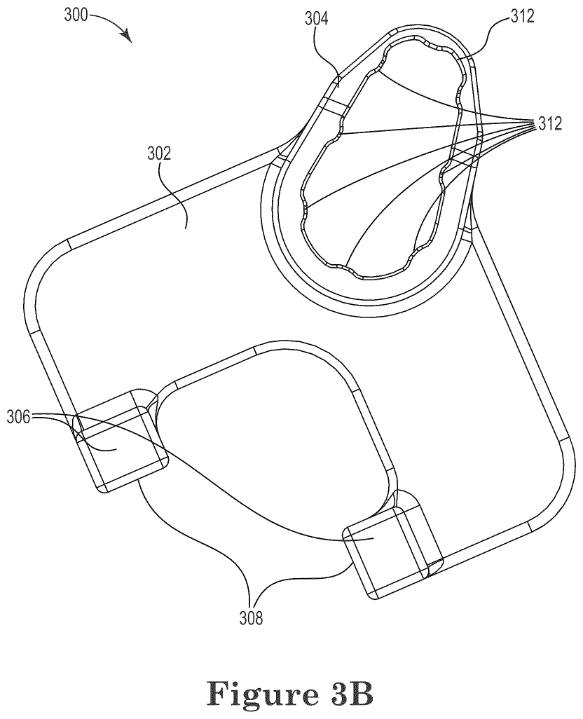

FIG. 3A shows a reinforcement support according to an embodiment. Reinforcement support 300 includes body 302, attachment interface 304, and support features 306.

Reinforcement support 300 is an example of a reinforcement support configured to be used as an insert in a reticle container. The reinforcement support 300 can be made of any suitable material or materials, such as one or more of a polyolefin material, a polycarbonate material, a polyether-ether ketone (PEEK) material, an elastomeric material, or the like. Suitable materials are materials having sufficient rigidity to restrict movement of a reticle contact. Suitable materials further can be selected based on cleanliness properties such as having suitable particle generation and/or offgassing properties for being used with photolithography reticles, and the like.

Body 302 is a main body of the reinforcement support 300 connecting the attachment interface 304 and the support features 306. Attachment interface 304 is provided at an end of body 302. Attachment interface can have any suitable shape for forming a mechanical connection with a feature of the reticle container. The mechanical connection can be, for example, a press-fit, a snap-fit, or the like. The feature of the reticle container which the reinforcement support 300 can be configured to connect to can be, for example, a corner contact, a recess, notch, groove, projection, flange, or any other suitable feature provided in the reticle container. In the embodiment shown in FIG. 3A, the attachment interface is configured to form a press-fit over a corner contact of the reticle container. The attachment interface 304 includes an opening configured to surround a portion of the corner contact of the reticle container, and one or more attachment features configured to form the press-fit, contacting said portion of the corner contact.

Support features 306 are features configured to restrict the movement of features of the corresponding corner contact. In an embodiment, support features 306 extend into a deflection path of a corresponding arm of a corner contact, so as to obstruct further deflection by said corresponding arm. In the embodiment shown in FIG. 3A, the support features are vertically extending posts having a square or rectangular cross-section including a flat face 310 facing outwards towards the reticle. The flat faces 308 can be configured such that when the reticle is in its ordinary position within the reticle container, the flat faces 308 will be spaced apart from the reticle. In an embodiment, the reticle can come into contact with the flat faces 308 to restrict movement of the reticle and prevent the reticle from being ejected. In other embodiments, the vertically extending posts can have an elliptical or circular cross-section providing a contact surface as opposed to the flat face 308.

FIG. 3B shows another view of the reinforcement support 300 of FIG. 3A. In the top view of FIG. 3B, attachment feature 304 can be seen as including a plurality of engagement features 310 distributed around inner perimeter 312. The engagement features 310 are configured to form a press-fit with a corner contact provided in a reticle container according to an embodiment. In the top view of FIG. 3B, the generally rectangular cross-section of the support features 306 discussed above can also be seen.

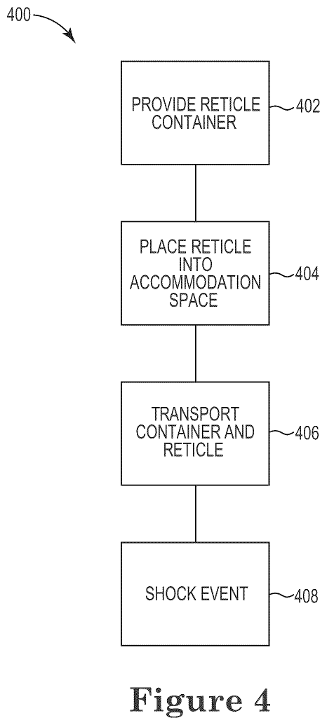

FIG. 4 shows a method according to an embodiment. Method 400 includes providing a reticle container 402, placing a reticle into an accommodation space of the reticle container 404, and transporting the reticle container and the reticle at 406. During the transporting at 406, the reticle container can experience a shock at 408.

A reticle container is provided 402. The reticle container can be a reticle container including reinforcement supports, such as the reticle container 100 or the reticle container 200 as described above and shown in FIGS. 1 and 2. The reticle container includes an accommodation space configured to receive a corresponding reticle and contacts for securing the position of the reticle through contact with non-functional portions of said reticle such as corner contacts 202 as described above and shown in FIG. 2.

A reticle is placed into an accommodation space of the reticle container 404. When placed in the reticle container at 404, the reticle can be contacted by, for example, contacts provided within the reticle container such as the corner contacts. The contact can retain the reticle in a desired position within the reticle container. The contact can be in proximity to reinforcement supports, with the reinforcement supports configured to restrict deflection of at least portions of the contact. The container can be closed to surround the reticle following placement of the reticle into the accommodation space at 404, and the container secured closed by any suitable closure such as one or more latches or the like.

Once the reticle is within the reticle container and the reticle container is closed, the reticle container and the reticle are transported at 406. The transportation can include any suitable manual or automated handling of the reticle container so as to transport the reticle from a first location, to a second location, with examples of such locations being areas within a semiconductor fabrication facility, reticle manufacture and/or patterning facilities, reticle storage areas, and the like.

During transportation at 406, a shock event can occur at 408. A shock event is an inadvertent sudden acceleration and/or deceleration of the reticle container containing the reticle. Examples of shock events that can occur at 408 include, for example, the reticle container being dropped, struck, or the like. The shock event can include impact on the reticle container on upper, lower, and/or side surfaces or at corners thereof. When the shock event occurs at 408, at least some of the contacts securing the reticle within the container can deform. Where the shock event at 408 causes deflection to a certain threshold, at least a portion of the contact comes into contact with the reinforcement support, thereby restricting further deformation of the contact. This can result in the contact retaining control of the reticle, reducing a chance of the reticle becoming displaced during the shock event occurring at 408. Further, depending on the severity of the shock event, the reticle can impact the reinforcement support on a suitable surface provided on said reinforcement support, limiting the extent to which the reticle can move within the reticle container upon occurrence of a shock event of sufficient severity at 408. Following the shock event, the contacts can push the reticle back into position within the reticle container, depending on the extent of displacement and the spring force that the reticle contacts can provide.

To model shock events such as those occurring at 408, test reticle containers were prepared by adding reinforcement supports as described above and shown in FIGS. 2 and 3 and described above, formed of PEEK material. The reinforcement supports were added to existing reticle containers, in this instance the RSP 200 reticle shipping container from Entegris, Inc. The containers were dropped onto a granite surface from heights starting at one inch, and incremented by one inch in successive tests. Failure was defined as the reticle being ejected from its corresponding reticle contacts within the container. Existing RSP 200 containers without the reinforcement supports were also tested. RSP 200 containers without the reinforcement supports showed ejection of the reticle when dropped from heights of 3 inches or less. Containers including the reinforcement supports did not fail until they were being dropped from heights of 14-20 inches, depending on the orientation of the reticle container when dropped.

### Aspects

It is understood that any of aspects 1-8 can be combined with any of aspects 9-15 or 16-20. It is understood that any of aspects 9-15 can be combined with any of aspects 16-19.

Aspect 1. A reticle container, comprising:
a first container segment,
a second container segment,
one or more corner contacts, each corner contact including one or more arms, each arm ending in a contact surface configured to contact a reticle within a reticle accommodation space defined by the first container segment and the second container segment; and
one or more reinforcement supports, each of the one or more reinforcement supports including support feature configured to contact at least one of the one or more arms when said at least one of the one or more arms is deflected to a threshold deflection.

Aspect 2. The reticle container according to aspect 1, wherein at least some of the one or more reinforcement supports extend from the first container segment.

Aspect 3. The reticle container according to any of aspects 1-2, wherein the support feature includes an elongated post.

Aspect 4. The reticle container according to any of aspects 1-3, further comprising one or more inserts, wherein at least some of the one or more reinforcement supports are provided on the one or more inserts.

Aspect 5. The reticle container according to aspect 4, wherein at least some of the one or more inserts are configured to attach to one of the one or more corner contacts.

Aspect 6. The reticle container according to any of aspects 4-5, wherein at least some of the one or more inserts are configured to attach to the first container segment.

Aspect 7. The reticle container according to any of aspects 1-6, wherein at least some of the reinforcement supports include a contact configured to face the reticle within the reticle accommodation space.

Aspect 8. The reticle container according to aspect 7, wherein the contact includes a flat surface.

Aspect 9. An article comprising a shipping constraint for a reticle container, the shipping constraint including:
an attachment interface configured to allow attachment of the shipping constraint to the reticle container; and
at least one reinforcement support, the reinforcement support including at least support feature configured to be contacted by an arm of a corner constraint of the reticle container, when said arm is deflected to a threshold deflection.

Aspect 10. The article according to aspect 9, wherein the attachment interface is an aperture configured to fit over a portion of the corner constraint.

Aspect 11. The article according to any of aspects 9-10, wherein the support feature includes an elongated post.

Aspect 12. The article according to any of aspects 9-11, wherein the reinforcement support includes a contact configured to face a reticle within a reticle accommodation space of the reticle container.

Aspect 13. The article according to aspect 12, wherein the contact includes a flat surface.

Aspect 14. The article according to any of aspects 9-13, wherein the article is formed of polycarbonate.

Aspect 15. The article according to any of aspects 9-13, wherein the article is formed of polyether-ether-ketone (PEEK).

Aspect 16. A method of handling a reticle, comprising:
providing a reticle container, the reticle container including a first container segment, a second container segment, a plurality of corner contacts configured to contact the reticle, and a plurality of reinforcement supports;
placing a reticle into a reticle accommodation space defined by the first container segment and the second container segment, such that the corner contacts are in contact with the reticle; and transporting the reticle container when the reticle is in the reticle accommodation space of the reticle container,
wherein when the reticle container is subjected to a shock, at least some of the corner contacts deflect such that said corner contacts come into contact with at least one of the reinforcement supports, thereby stopping further deflection of said corner contacts.

Aspect 17. The method according to aspect16, wherein the reinforcement supports are provided on an insert configured to be attached to the reticle container, and the method further includes installing the insert into the reticle container.

Aspect 18. The method according to any of aspects 16-17, wherein when the reticle container is subjected to the shock, the reticle comes into contact with at least one flat surface provided on at least one of the reinforcement supports.

Aspect 19. The method according to any of aspects 16-18, wherein the shock is a dropping of the reticle container from a height of 12 inches or less, and the reticle remains in contact with the corner contacts following the shock.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article for holding a reticle, comprising:
A reticle container have first container segment and a second segment,
one or more corner contacts, each corner contact including one or more arms, each arm ending in a contact surface configured to contact a reticle within a reticle accommodation space defined by the first container segment and the second container segment; and
one or more reinforcement supports, each of the one or more reinforcement supports including support feature configured to contact at least one of the one or more arms when said at least one of the one or more arms is deflected to a threshold deflection.

2. The article of claim 1, wherein at least some of the one or more reinforcement supports extend from the first container segment.

3. The article of claim 1, wherein the support feature includes an elongated post.

4. The article of claim 1, further comprising one or more inserts, wherein at least some of the one or more reinforcement supports are provided on the one or more inserts.

5. The article of claim 4, wherein at least some of the one or more inserts are configured to attach to one of the one or more corner contacts.

6. The article of claim 4, wherein at least some of the one or more inserts are configured to attach to the first container segment.

7. The article of claim 1, wherein at least some of the reinforcement supports include a contact configured to face the reticle within the reticle accommodation space.

8. The article of claim 7, wherein the contact includes a flat surface.

9. An article comprising a shipping constraint for a reticle container, the shipping constraint including:
an attachment interface configured to allow attachment of the shipping constraint to the reticle container; and
at least one reinforcement support, the reinforcement support including at least support feature configured to be contacted by an arm of a corner constraint of the reticle container, when said arm is deflected to a threshold deflection.

10. The article of claim 9, wherein the attachment interface is an aperture configured to fit over a portion of the corner constraint.

11. The article of claim 9, wherein the support feature includes an elongated post.

12. The article of claim 9, wherein the reinforcement support includes a contact configured to face a reticle within a reticle accommodation space of the reticle container.

13. The article of claim 12, wherein the contact includes a flat surface.

14. The article of claim 9, wherein the article is formed of polycarbonate.

15. The article of claim 9, wherein the article is formed of polyether-ether-ketone (PEEK).

16. A method of handling a reticle, comprising:
providing a reticle container, the reticle container including a first container segment, a second container segment, a plurality of corner contacts configured to contact the reticle, and a plurality of reinforcement supports;
placing a reticle into a reticle accommodation space defined by the first container segment and the second container segment, such that the corner contacts are in contact with the reticle; and
transporting the reticle container when the reticle is in the reticle accommodation space of the reticle container,
wherein when the reticle container is subjected to a shock, at least some of the corner contacts deflect such that said corner contacts come into contact with at least one of the reinforcement supports, thereby stopping further deflection of said corner contacts.

17. The method of claim 16, wherein the reinforcement supports are provided on an insert configured to be attached to the reticle container, and the method further includes installing the insert into the reticle container.

18. The method of claim 16, wherein when the reticle container is subjected to the shock, the reticle comes into contact with at least one flat surface provided on at least one of the reinforcement supports.

19. The method of claim 16, wherein the shock is a dropping of the reticle container from a height of 12 inches or less, and the reticle remains in contact with the corner contacts following the shock.
